(19) United States
(12) Patent Application Publication
(10) Pub. No.: US 2026/0021556 A1
(43) Pub. Date: Jan. 22, 2026

(54) DRESSER FOR CMP PROCESS AND MATHOD AND PROCESS FOR CREATING AND MONITORING POLISHING PAD PORES

(71) Applicant: H.P.B. OPTOELECTRONICS CO., LTD., Taichung City (TW)

(72) Inventors: Hsuan-Yueh Hsu, Taichung City (TW); Yuan-Ching Chao, Taichung City (TW)

(21) Appl. No.: 19/257,769

(22) Filed: Jul. 2, 2025

Related U.S. Application Data
(60) Provisional application No. 63/673,191, filed on Jul. 19, 2024.

(51) Int. Cl. B24B 53/017; B24B 37/005

(52) U.S. Cl. CPC B24B 53/017; B24B 37/005

(57) ABSTRACT

A dresser for a CMP process has a substrate, at least one sheet body, and a modular grinding unit. The least one sheet body is disposed on a side face of the substrate. The modular grinding unit is disposed on the at least one sheet body and has multiple structures disposed on the at least one sheet body at spaced intervals. Each one of the multiple structures has a convex portion, and the convex portions of the multiple structures have different heights.

### CROSS-REFERENCE TO RELATED INVENTIONS

The present application claims benefit of U.S. provisional application No. 63/673,191, filed on Jul. 19, 2024, under 35 U.S.C. 119(e), the content of which is hereby incorporated by reference in its entirety.

### BACKGROUND OF THE INVENTION

### 1. Field of the Invention

The present invention relates to a CMP process, apparatus, and monitoring method, and more particularly to a CMP process, apparatus, dresser, and monitoring method for a polishing pad that can easily penetrate into the polishing pad, can form regionalized co-height and co-planar grooves on the polishing pad, can remove glaze or dirt from the polishing pad, can regenerate fluff to make the surface roughness of the polishing pad uniform, and can create a lateral morphology of the polishing pad groove, which is beneficial to the nutrition of the polishing liquid.

### 2. Description of Related Art

Chemical-Mechanical Polishing (CMP) is the main wafer planarization process in semiconductor manufacturing. When the feature size of a semiconductor wafer is less than 0.35 micrometers (μm), global planarization must be performed. CMP is currently the world's most efficient planarization technology. As the line width of integrated circuits continues to reduce, the optical numerical aperture (N.A.) value of Deep Ultraviolet Lithography (DUV)/Extreme Ultraviolet (EUV) continues to increase, and the depth of field (DoF) becomes shorter and shorter. Therefore, the wafer planarization process must be performed before exposure, development, and etching. Through the CMP process, a well-distributed dresser (or diamond disc) is used to regenerate the surface geometric configuration of a polishing pad. For example, for extreme ultraviolet (EUV) light source technology, its depth of field (DoF) is shown in the following formula:

$$DoF = K \cdot λ / {NA}^{2}$$

Wherein, λ is the wavelength and NA is the numerical aperture. When the wavelength is a constant of 13.5 nm, and the NA is assumed to be 0.55, the depth of field obviously needs to be less than 15 nm. In other words, if the wafer cannot be ground to this flatness level, exposure and development will fail. Therefore, the common height of high end of a cone of a conventional dresser is very important, because it determines the depth, width, and amount of grooves produced on a polishing pad when the conventional dresser is scratched, as well as whether the created surface hairs can contain more chemical grinding fluid (or polishing fluid). Secondly, the common height of high end of the cone of each regionalized module forms the coplanarity of the conventional dresser. However, with reference to FIG. 25, if the high ends of particles of the conventional dresser are too high or the cross-sections are too large, it will cause the polishing pad to produce an excessively high protrusion 401 (the unit pressure of the wafer contact surface will be higher), thereby scratching the surface of the wafer.

However, as shown in FIG. 25, if the high end of one of the cones on the conventional dresser is higher than the high ends of a group of cones, the polishing pad 400 will produce an excessively high protrusion 401, thereby indirectly scratching the surface of the wafer; the protrusion 401 is produced because the polishing pad 400 is deformed when the high end of the conventional dresser is pressed against the polishing pad 400, and then ridges are generated during the lateral movement. Therefore, the control of the common height and coplanarity of the high ends of the cones becomes the first requirement for improvement of the conventional dresser. Furthermore, in the CMP process, the conventional dresser creates grooves on the polishing pad 400 by pressing down and operating, so that the chemical polishing liquid can fill the grooves. Under the relative movement between the wafer and the polishing pad 400, the tiny abrasive particles in the chemical polishing liquid (polishing liquid) grind the surface of the wafer and oxidize or corrode the metal at the same time. However, due to the action of the wafer during the polishing process, the chemical polishing liquid will be quickly lost due to the centrifugal force of rotation, and the cost of chemical polishing liquid accounts for more than 50% of all consumables in the CMP process. Therefore, how to retain the polishing liquid on the polishing pad requires the continuous creation of new pores in the conventional dresser, which becomes the second requirement for the improvement of the conventional dresser. In addition, with reference to FIG. 26, in the CMP process, during the chemical mechanical polishing process of the conventional dresser X and the wafer by pressing down and operating on the polishing pad 400, as time accumulates, when the temperature of the polishing pad 400 exceeds 35° C., the variation of the material removal rate (MRR) will increase rapidly, which will affect the subsequent polishing quality of the wafer.

Furthermore, in the CMP process, the relative movement between the conventional dresser and the polishing pad 400 will scratch grooves on the polishing pad 400 and create new surface fluff. Controlling the protrusions 401 of the polishing pad 400 and reducing the uniformity of the overall roughness of the polishing pad 400 are the third requirement for improving the conventional dresser.

On the other hand, in the CMP process, when the conventional dresser creates grooves on the polishing pad 400 by pressing down and operating, the polishing pad 400 may generate resistance, deformation, and tearing due to the relative movement between the conventional dresser and the polishing pad 400. However, since the viscoelasticity of the polishing pad 400 contains deformation, the larger the cone angle of the conventional dresser is, the greater the reaction force against piercing the polishing pad 400 is, and it is difficult to control the correct depth of piercing the polishing pad 400. Furthermore, the other force of the cone will cause the groove edge of the polishing pad 400 to form the protrusion 401, which will seriously affect the flatness of the surface of the wafer. Therefore, the sharp protrusions on the diamond cone surface are conducive to the puncture of the polishing pad 400 when it is downward, and reduce the deformation of the metal body of the conventional dresser and the polishing pad 400. At the same time, it can qualitatively/quantitatively characterize and produce the fourth-dimensional grooves avoiding the traditional method for manufacturing the polishing pad 400: a plastic micro-foam injection molding technology, such as MuCell®, critical micro foam injection molding the polishing Pad 400. The polishing pad 400 has holes of varying sizes formed during cooling after injection molding, making it difficult to control the overall deformation during polishing, and this is the fourth requirement for the improvement of the conventional dresser.

With reference to FIG. 27, a stress-strain diagram, the following equation can be used to derive from this information in a simplified manner:

$$σ = Fc / A$$

σ is applied stress, Fc is compressive force, and A is cross-sectional area of the test material; for a constant rate of deformation, the strain is measured using the following equation:

$$ε = v Δ t$$

ε is strain, ν is downward velocity of the cone, and Δt is equal to the rate of deformation of the specimen, after a period of time, where a straight line in the elastic region, that is, before the maximum applied load, and based on Hooke's law:

$$σ ( t ) = E \cdot ε ( Δ t ) \\ ε = v \cdot Δ t / L 0 \\ σ = E \cdot ε ( t ) = E \cdot v \cdot Δ t / L 0 \\ E = σ / ε$$

σ is stress, E is Young's modulus, ε(t) is time-varying strain, v is constant velocity, Δt is the elapsed time, and L0 is original length.

Although the relevant data can be obtained by calculating through the above-listed related equations, the current operation mode cannot timely detect whether the surface texture of the polishing pad 400 and the high ends of the cones of the conventional dresser are worn, and adjustments can only be made when problems occur in the subsequent process, which will affect the quality of the wafers being ground during this period.

For example, as disclosed in TW Patent No. 436375B, TW Patent Publication No. 202004886A, TW Patent No. 1813551, and TW Patent No. 1741865, although the conventional dresser has mechanical properties, surface morphology, and porosity/fluff creation for the polishing pad's PU polyurethane, which are helpful for the polishing effect, there is a lack of a polishing liquid retention method and an inability to effectively control the effects of thermal expansion and poor surface texture of the dresser and polishing pad in the overall CMP process cost control, all of which need to be improved.

Furthermore, the above-mentioned TW 436375B, TW 202004886A, TW 1813551, and TW 1741865 all illustrate that the diamond dressers help the polishing effect of the mechanical properties, surface morphology, and porosity/fluff creation of the polishing pad PU polyurethane. Even so, the functions can only be achieved: such as carving the polishing pad grooves and removing debris. For the overall CMP process cost control (such as flatness), the lack of polishing liquid retention method and the inability to effectively qualitatively/quantitatively control the polishing pad grooves, the traditional polishing pad method is supercritical micro-foaming injection molding, and indefinite pores are formed after the polishing pad is cooled.

To overcome the shortcomings, the present invention tends to provide a CMP process, apparatus, dresser, and monitoring method for a polishing pad to mitigate the aforementioned problems.

### SUMMARY OF THE INVENTION

The main objective of the invention is to provide a CMP process, apparatus, dresser, and monitoring method for a polishing pad that can easily penetrate into the polishing pad, can form regionalized co-height and co-planar grooves on the polishing pad, can remove glaze or dirt from the polishing pad, can regenerate fluff to make the surface roughness of the polishing pad uniform, and can create a lateral morphology of the polishing pad groove, which is beneficial to the nutrition of the polishing liquid.

A dresser for a CMP process in accordance with the present invention has a substrate, at least one sheet body, and a modular grinding unit. The least one sheet body is disposed on a side face of the substrate. The modular grinding unit is disposed on the at least one sheet body and has multiple structures disposed on the at least one sheet body at spaced intervals. Each one of the multiple structures has a convex portion, and the convex portions of the multiple structures having different heights.

A CMP apparatus in accordance with the present invention has a body, a dresser, and a polishing pad. The body has a processing end and a processing platform. The dresser is disposed on the processing end of the body to make each one of the structures on the at least one sheet body face the processing platform. The polishing pad is disposed on the processing platform of the body and is polished by the dresser.

A CMP process in accordance with the present invention comprises preparing a CMP apparatus, driving the dresser to move and rotate toward the polishing pad via the processing end of the body, and polishing the polishing pad by the convex portions of each structure of the dresser to form regionalized polishing pad grooves with the common height and the coplanarity on the polishing pad, and to form lateral morphologies on the polishing pad through the at least one secondary convex portion of each structure.

A method for monitoring pores of a polishing pad during a CMP process in accordance with the present invention includes preparing a CMP apparatus, arranging a lens module on the CMP apparatus and using a meta-lens to observe micro features and perform 3D surface texturing and flatness monitoring by optical shearing interferometry, using an AI system to identify the polishing pad, polishing fluids, and a wafer by refractive index, reflected light intensity, and scattering data, and monitoring the pores of the polishing pad via the learning of the AI system to judge tiny features of the polishing pad.

Other objects, advantages and novel features of the invention will become more apparent from the following detailed description when taken in conjunction with the accompanying drawings.

### BRIEF DESCRIPTION OF THE DRAWINGS

FIG. 1 is a perspective view of a dresser for a CMP process in accordance with the present invention;

FIG. 2 is a perspective view of a first embodiment of a sheet body of the dresser for a CMP process in FIG. 1;

FIG. 3 is an enlarged perspective view of a second embodiment of a sheet body of the dresser for a CMP process in FIG. 1;

FIG. 4 is an enlarged perspective view of a third embodiment of a sheet body of the dresser for a CMP process in FIG. 1;

FIG. 5 is top side view of the third embodiment of a sheet body of the dresser for a CMP process in FIG. 4;

FIG. 6 is a cross-sectional side view of the third embodiment of a sheet body of the dresser for a CMP process across line 6-6 in FIG. 5;

FIG. 7 is an enlarged cross-sectional side view of a third embodiment of a sheet body of the dresser for a CMP process in FIG. 6;

FIG. 8 is an enlarged cross-sectional perspective view of a fourth embodiment of a sheet body of a dresser for a CMP process in FIG. 1;

FIG. 9 is an enlarged cross-sectional perspective view of a fifth embodiment of a sheet body of a dresser for a CMP process in FIG. 1;

FIG. 10 is an enlarged perspective view of a sixth embodiment of a sheet body of a dresser for a CMP process in FIG. 1;

FIG. 11 is an operational side view of the dresser for a CMP process in FIG. 1, dressing a polishing pad;

FIG. 12 is another operational side view of the dresser for a CMP process in FIG. 1, dressing the polishing pad;

FIG. 13 a top side view of another embodiment of a dresser for a CMP process in accordance with the present invention;

FIG. 14 is an enlarged perspective view of a further embodiment of a sheet body of a dresser for a CMP process in accordance with the present invention;

FIG. 15 is an enlarged perspective view of another embodiment of a sheet body of a dresser for a CMP process in accordance with the present invention;

FIG. 16 is an enlarged perspective view of another embodiment of a sheet body of a dresser for a CMP process in accordance with the present invention;

FIG. 17 is an operational side view of a CMP apparatus in accordance with the present invention, grinding a wafer;

FIG. 18 is another operational side view of the CMP apparatus in accordance with the present invention, grinding the wafer;

FIG. 19 is an operational perspective view of the dresser for CMP process in accordance with the present invention, dressing the polishing pad;

FIG. 20 is another operational perspective view of the dresser for CMP process in accordance with the present invention, dressing the polishing pad;

FIG. 21 is an operational side view of a lens module of the CMP apparatus in accordance with the present invention;

FIG. 22 is a perspective view of the lens module of the CMP apparatus in FIG. 21;

FIG. 23 is an enlarged perspective view of the lens module of the CMP apparatus in FIG. 22;

FIG. 24 is a schematic diagram of an operation interface of an AI system of the CMP apparatus in accordance with the present invention;

FIG. 25 is an operational side view of a dresser for a CMP process in accordance with the prior art;

FIG. 26 is a diagram showing relationship between material removal rate and temperature of a dresser for a CMP process, dressing a polishing pad; and

FIG. 27 is a diagram showing relationship of stress-strain of a dresser for a CMP process, dressing a polishing pad.

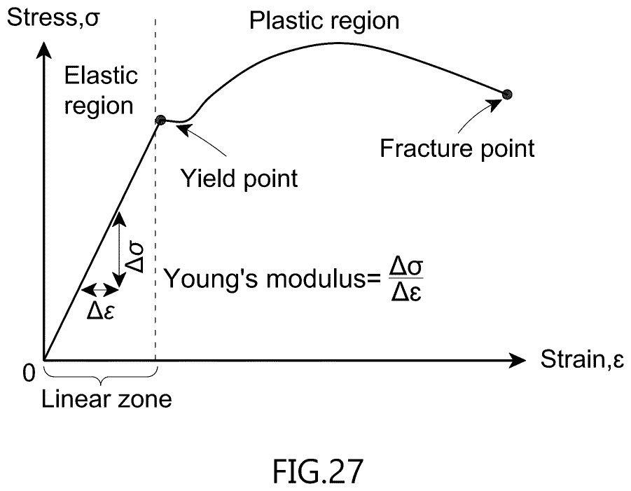

### DETAILED DESCRIPTION OF PREFERRED EMBODIMENTS

The invention is to provide a CMP process, apparatus, dresser, and monitoring method for a polishing pad.

The present invention designs and manufactures single crystal/polycrystalline diamond grains or hard material modules with a Vickers hardness exceeding 1000 kgf/mm² on a dresser to meet the following functions of the dresser:

First, the highest point of the die set of the dresser can more easily penetrate the polishing pad and regionally scribe the polishing pad grooves with the same height and plane.

The specific description of the cone of common height or coplanarity in the CMP process can be divided into polishing pads and dressers:

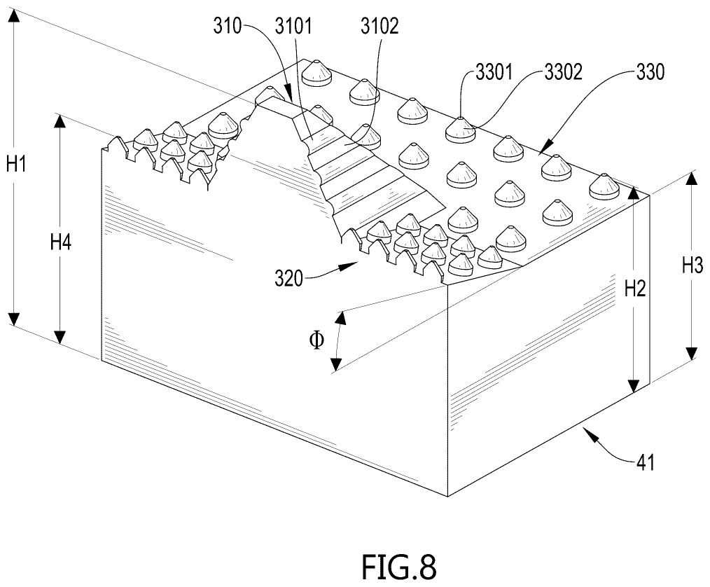

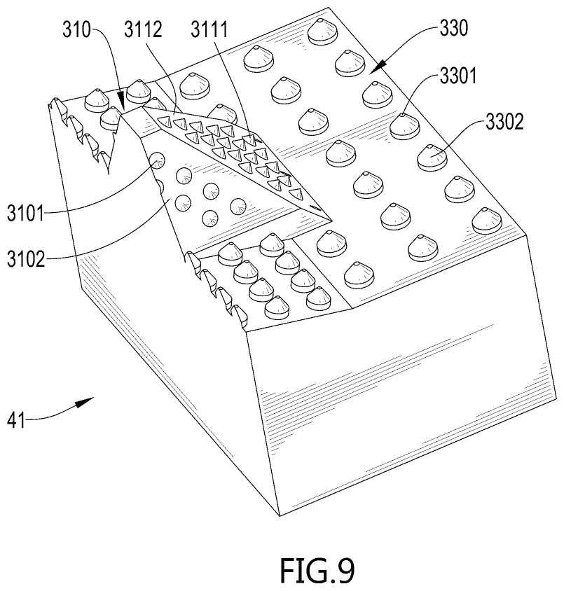

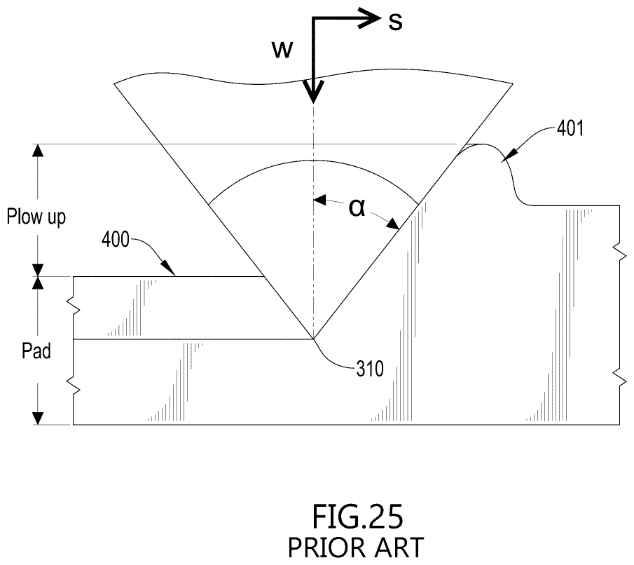

1. Common height and coplanarity of polishing pads: after the polishing pad is trimmed by the dresser, the polishing pad plows and polishes; with reference to FIG. 25, when a cone high point 310 on the dresser is plowed onto the polishing pad 400, the cone high point 310 on the dresser first approaches the polishing pad 400 from a far end, with a downward pressure stroke W and a rotation of the polishing pad 400, and the dresser begins to penetrate the polishing pad 400 in a S direction due to a movement of a swing arm. The surfaces of geometric configuration generated from the cone high point 310 force the polishing pad 400 to gradually deform concavely under the action of elastic and plastic stresses along the moving path. Because of the interaction between the plastic flow of the polishing pad 400 and the shape of the cone high point 310, the protrusion 401 has a height (PLOW UP). This height and shape are completely determined by the shape of the cone high point 310 and the influence of the speed of the polishing pad 400, the movement of the swing arm (including the speed of the dresser), and the physical properties of the polishing pad 400. When a plurality of cone high points 310 with the common height are engraved on the polishing pad 400 under the above-mentioned movement, a protrusion 401 with the common height or the coplanarity is generated. With reference to FIG. 8, during a carving process, the cone high point 310 generates protrusions 3101, 3111, 3301 (textural pattern) and the cone surfaces 3102, 3112, 3302 (surface morphology). The protrusion 3101 shown in FIG. 9 is a deformation of the protrusion 3101 in FIG. 8. Strictly speaking: wafer grinding in the range of 12″ (300 mm) is a relatively large area, and the CMP apparatus relies on the large-area layout of the polishing pad 400 to grind the wafer. When the diameter of the polishing pad 400 is greater than 700 mm, the wear rate will change with the linear speed of the circle radius, thus affecting the overall wafer flatness result, so it is necessary to regionally compensate for the protrusions 401 with the common height or plane height of the polishing pad 400 to achieve high-precision flatness of the wafer. The micro-gaps on the protrusions 401 and the abrasives on the polishing liquid can grind the wafer.

2. Common height and coplanarity of dressers: the dresser discussed in the present invention does not adopt a hard-soldering process, but is a dresser formed by post-processing high-hardness materials. For example: ultrafast laser processing, electron beam, plasma, discharge processing, etc. For example: ultrafast laser processing (1064 nm, 1030 nm, <532 nm, etc., the shorter the wavelength, the higher the processing precision; scanning frequency nanoseconds<picoseconds<femtoseconds, the higher the frequency, the lower the accumulated energy, and the smaller the change in the physical properties of the material.) is used to perform morphology removal processing on single crystal diamond or polycrystalline diamond or materials with a Mohs hardness of more than 9.5. Since the ultrafast laser can change the position of the workpiece on the 4˜5-axis machine through the galvanometer and the matching workpiece, the processing path is changed, so it is possible to perform arbitrary morphology and regional instant processing on the high-hardness materials, which benefits from the high-precision optical system configuration (such as a larger N.A. of the optical lens module). For example, the diamond group in the outer circle of the dresser is higher than the diamond group in a second/third inner circle, and each group in each zone must establish a full common height (common height ranges between 3 um˜10 um), and the same morphology is processed to form a coplanarity of the protrusions 401 of the polishing pad 400, and even the precision processing of morphology more than 3D is easier to master. For example, the difference in common height between the diamond group in a first zone and the diamond group in a second zone is 5˜20 um, which is not a constant, but is based on the wafer flatness requirements. Further monitor the coplanar results of the region when the polishing pad 400 is monitored. If a 12″ wafer is divided into 8 areas by radius, the corresponding polishing pad 400 has at least 8 areas covering the area of the wafer. After monitoring the flatness of Area 8 and Area 7, the dresser needs to form a coplanar creation for Area 8 and Area 7. That is, according to the flatness of the polishing pad 400, the diamond height of each area of the diamond dresser is dressed (real-time laser compensation) to form a coplanarity of the protrusions 401 with Area 8 and Area 7 of the polishing pad 400.

3. According to the above description, the area common height and coplanarity can be set at the initial stage of the dresser. After the polishing pad 400 is dressed and the wafer is ground, the flatness monitoring statistics are obtained, and the laser real-time processing data of the area common height and coplanarity of the diamond disc dresser is deduced. After the laser real-time trimming, the diamond dresser will form a wafer flattening target. Therefore, the height of the diamond dresser in each area after the laser real-time trimming is not necessarily the same as the original height, and it is also possible that Area 7 is lower than Area 8 and Area 6.

Second, the cone surface removes the glazed surface or dirt from the polishing pad 400 (Glazing).

Third, regenerate more hairs to make the surface roughness of the polishing pad 400 uniform.

Fourth, the creation of the lateral morphology of grooves of the polishing pad 400 is beneficial to the nourishment of the polishing liquid.

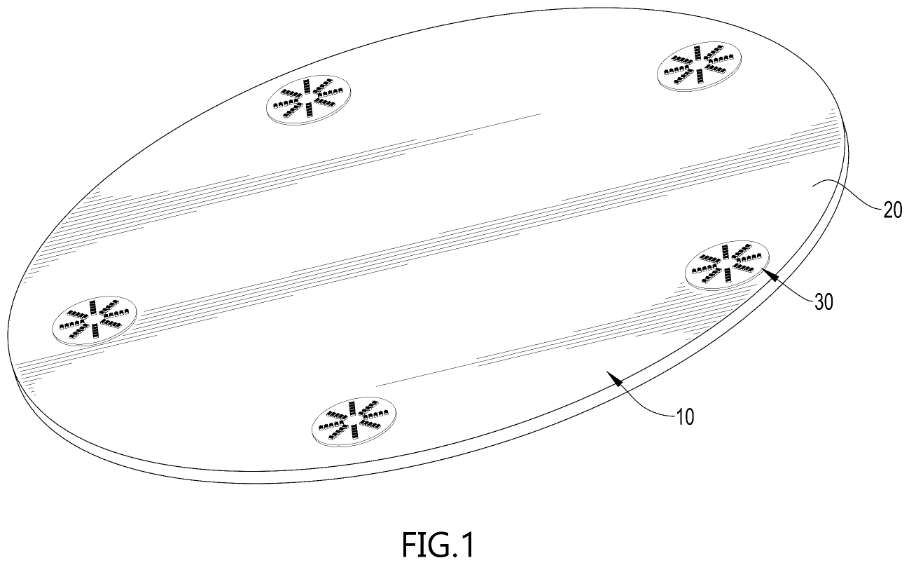

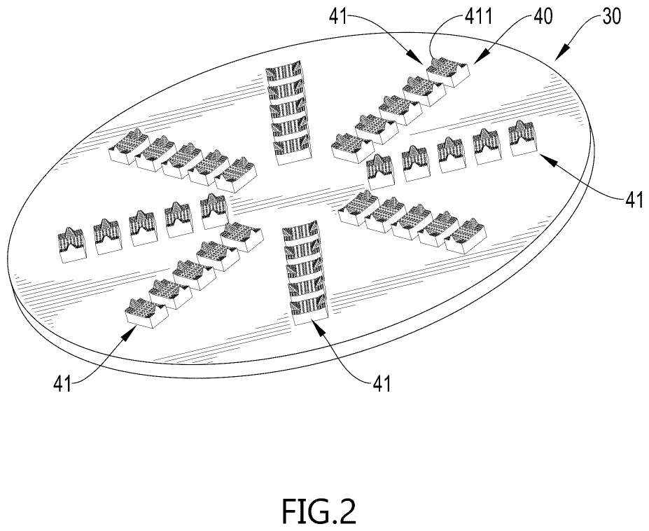

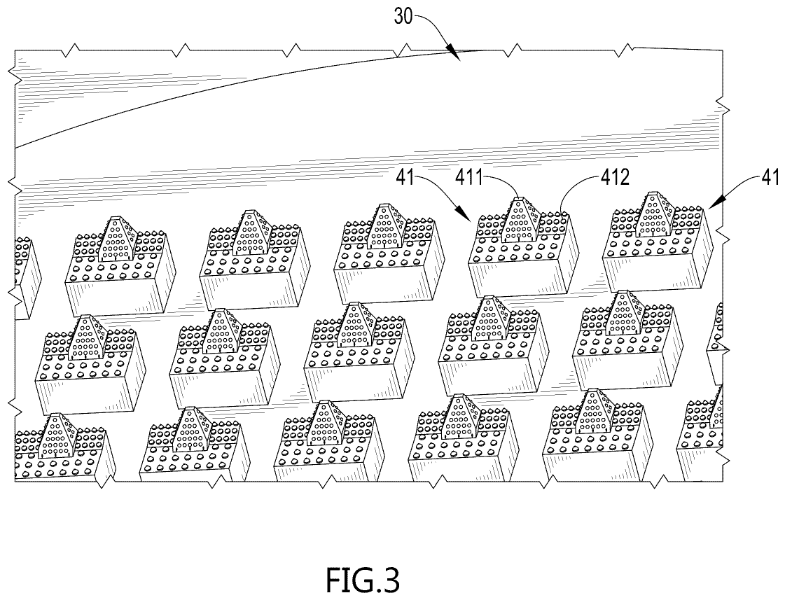

With reference to FIGS. 1 to 3, FIG. 1 is a partial schematic diagram of an embodiment of a dresser 10 of the present invention. FIG. 2 is a schematic diagram of a first embodiment of the modular cone configuration on a sheet body of the dresser 10 of the present invention, and FIG. 3 is a partially enlarged schematic diagram of a second embodiment of the modular cone high point configuration on a sheet body of the dresser 10 of the present invention. In some embodiments, the dresser 10 (or diamond disc) of the present invention is divided into several parts, the first is a substrate 20 (metal body, generally corrosion-resistant stainless steel metal, such as 316, 304) that can be fixed on a swing arm of a CMP apparatus, and the second is a plurality of sheet bodies 30 protruding from the metal body toward the polishing pad, may also be diamond-like films or resins with local acid- and alkali-resistant materials coated on the sheet body 30. The third is a combination of the sheet body 30 and the metal body. The fourth is the single crystal/polycrystalline diamond or a Vickers hardness exceeding 1000 kgf/mm² (i.e., a structure) on the sheet body 30. The sheet body 30 has a matrix and modular high-hardness cones formed by various single crystal/polycrystalline diamonds or a Vickers hardness exceeding 1000 kgf/mm² or a single sheet, and the cone height, morphology, and mutual spacing are not limited here.

The sheet bodies 30 are annularly arranged on the substrate 20 at spaced intervals, and each sheet body 30 has a modular grinding unit 40, and the modular grinding unit 40 has multiple structures 41, and each structure 41 has a convex portion 411, and each convex portion 411 can be a cone. These cones can be arranged on the sheet body 30 in a linear and radial manner as shown in FIGS. 1 and 2, or can be arranged in a matrix manner as shown in FIG. 3, but are not limited to being arranged in any of the above manners, and can also be arranged on the sheet body 30 in a randomly distributed manner.

Furthermore, the cone of the dresser 10 of the present invention comprises hard materials with a Vickers hardness exceeding 1000 kgf/mm², such as diamond, silicon dioxide, boron carbide, etc. The cone of the dresser 10 is disposed away from a direction of the substrate 20, but is not limited to a pointed cone, that is, a point, a surface end, or a line end, etc.

In the above embodiments, the substrate 20 of the dresser 10 of the present invention can be coated with a resin by evaporation or sputtering or by applying a diamond-like film or colloid spraying, so as to avoid the polishing liquid from oxidizing and corroding metal objects, thereby causing adverse effects on wafer polishing. Further, in the above embodiments, the multiple sheet bodies 30 on the dresser 10 of the present invention can be coated with a resin by evaporation or sputtering or by applying a diamond-like film or colloid spraying, so as to avoid the polishing liquid from oxidizing and corroding metal objects, thereby causing adverse effects on wafer polishing.

In the above embodiments, the single crystal/polycrystalline diamond or Vickers hardness exceeding 1000 kgf/mm² structure 41 on the sheet body 30 has various matrix and modular cone height morphologies and mutual spacings. The single crystal/polycrystalline diamond or Vickers hardness exceeding 1000 kgf/mm² structure 41 can be subjected to geometric configuration with high-precision engraving by femtosecond laser (point or line laser).

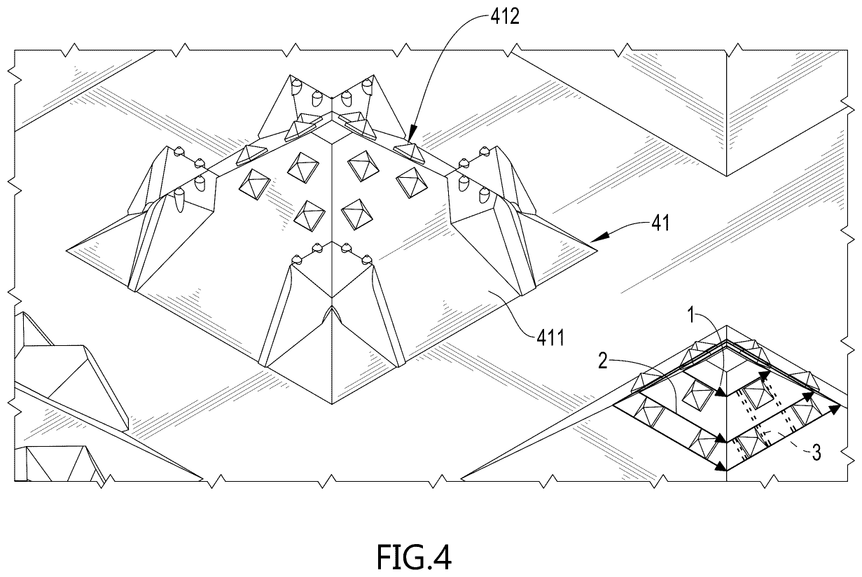

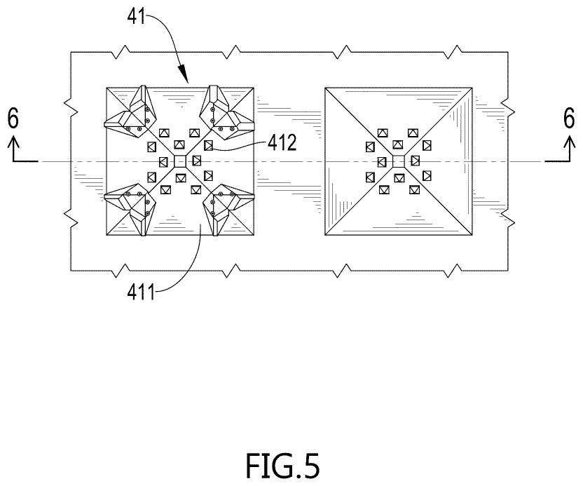

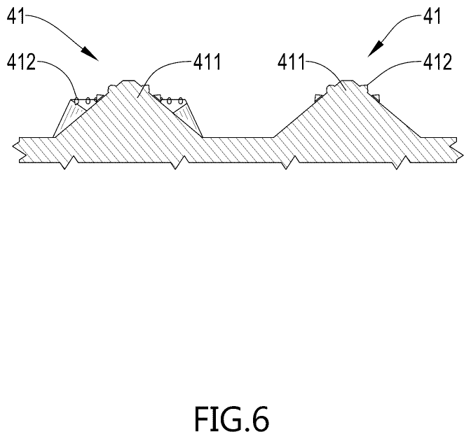

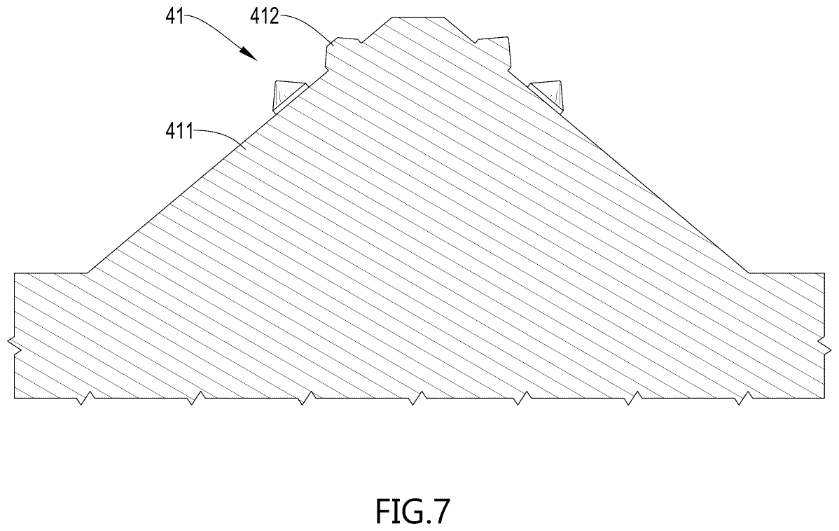

In the above-mentioned embodiments, in the femtosecond laser (point or line laser), the line laser is to configure a laser beam into 0-order, ±1-order, ±2-order, ±3-order, etc., multiple point light sources with equivalent energy are assembled into a line light source, or a matrix point light source, through a diffraction element, to perform morphology and height engraving in all directions of single crystal/polycrystalline diamond or a Vickers hardness exceeding 1000 kgf/mm² structure 41. With reference to FIG. 4, appropriate laser trajectories \textcircled{1}2 can be set by computer-aided drawing to create the main cone (i.e., the convex portion 411) and to create the secondary cone (i.e., the secondary convex portion 412) by trajectory \textcircled{3}. With reference to FIG. 5, it is a top view schematic diagram of the cones of the dresser 10 after laser processing, and FIG. 6 is a cross-sectional side view of the cones of the dresser 10 across line 5-5 in FIG. 5, and FIG. 7 is a cross-sectional side view of a part of one of the cones (right side) of the dresser 10.

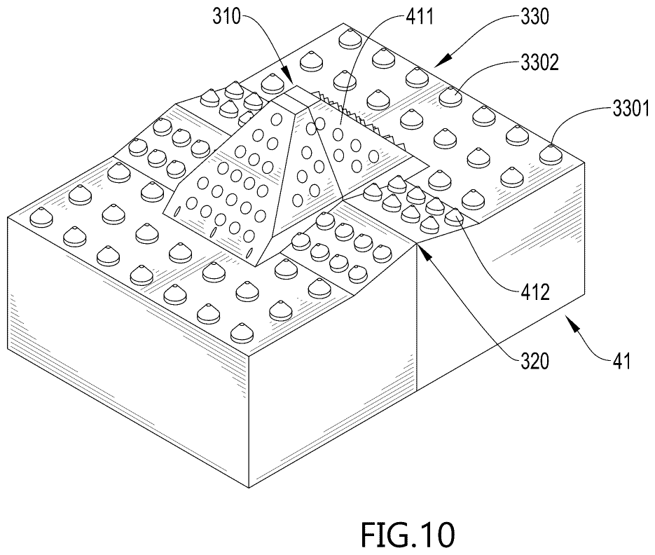

With reference to FIGS. 8 and 9, there are schematic diagrams of the cross-sectional perspective views of the processing of the cone morphology by the composite functional femtosecond laser, and the cone peak 320 forms an angle with the surface 330, and this angle is at least 1 degree. With reference to FIG. 10, it is another schematic diagram of the cone appearance after the composite functional femtosecond laser. In FIGS. 8 and 9, 3101/3111 are the lateral objects of the cone high point 310, so that the lateral morphology of the polishing pad formed with grooves can accommodate more polishing liquid, and can continuously send the polishing liquid from the pores to the wafer and the polishing pad through the movements of compression and expansion during the grinding process. Therefore, the lateral morphology of the diamond cone becomes the second requirement of the diamond dresser is to retain the polishing liquid in the polishing pad. In FIG. 9, H1 is one of the highest points of the total height of the dresser area, H3 is the lowest position of the sheet body 30, and H2/H4 is the height of the protrusion on the sheet body 30, which retains more polishing liquid through the morphology and surface tension.

In the above embodiments, the single crystal/polycrystalline diamond on the sheet body 30 has various diamond grain height morphologies and mutual spacings, the single crystal/polycrystalline diamond is coated with diamond powder on a filament, and its lattice is 111, and the morphology and height of the single crystal/polycrystalline diamond (lattice 100) are engraved. The diamond material is removed through the 111 lattice whose hardness and wear resistance are higher than the 100 lattice, and the filament coated with 111 lattice diamond abrasive is driven by the wheel structure to grind the morphology of the 100 single crystal.

In the above embodiments, the single crystal/polycrystalline diamond on the sheet body 30 has various cone side morphologies and mutual spacings on the single crystal/polycrystalline diamond or a Vickers hardness exceeding 1000 kgf/mm². The single crystal diamond sheet or a Vickers hardness exceeding 1000 kgf/mm² is morphologically and highly engraved by a femtosecond laser (point or line laser).

In the above embodiments, the single crystal diamond on the sheet body 30 has various diamond grain side morphologies and mutual spacings, and the single crystal diamond sheet is engraved with single gold diamond morphology and height using diamond powder on a filament (single filament or multiple filaments).

In the above embodiments, the Vickers hardness of the sheet body 30 exceeds 1000 kgf/mm². The sheet body can have various cone heights, various cone side morphologies, and mutual spacing, which are not limited here, and can form the required structure by 3D layered modeling.

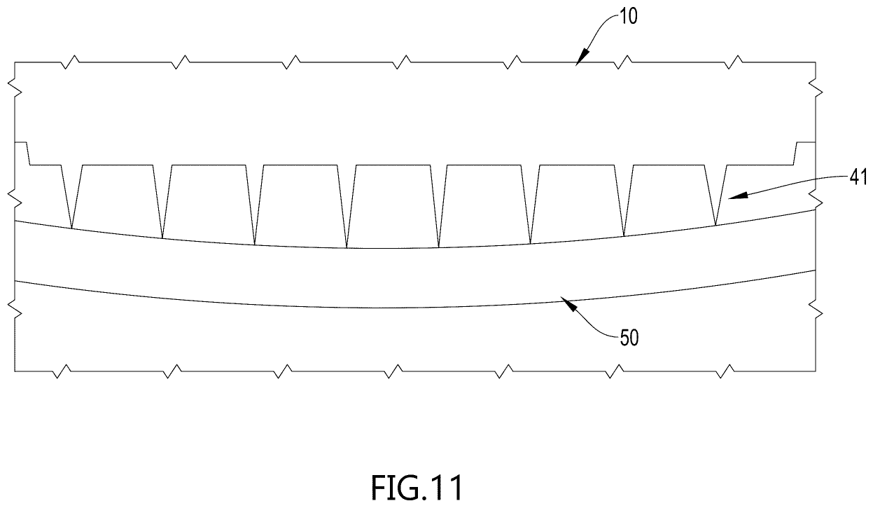

In the above embodiments, the single crystal/polycrystalline diamond or Vickers hardness exceeding 1000 kgf/mm² on the sheet body 30 is arranged in a symmetrical pattern with a certain ratio. Therefore, the higher cone tip must have multiple said the higher cone high points 310 on both sides of the scratching direction to make the lower cone peak 320 press the polishing pad, as in the embodiment, it is an array greater than 2 times, 3 times, 4 times . . . <20 times. With reference to FIG. 11, the cone high point 310 on the sheet body 30 and the cone peak 320 form a gradient height, which is conducive to piercing the polishing pad, that is, it is designed to gradually form a gradient height outward.

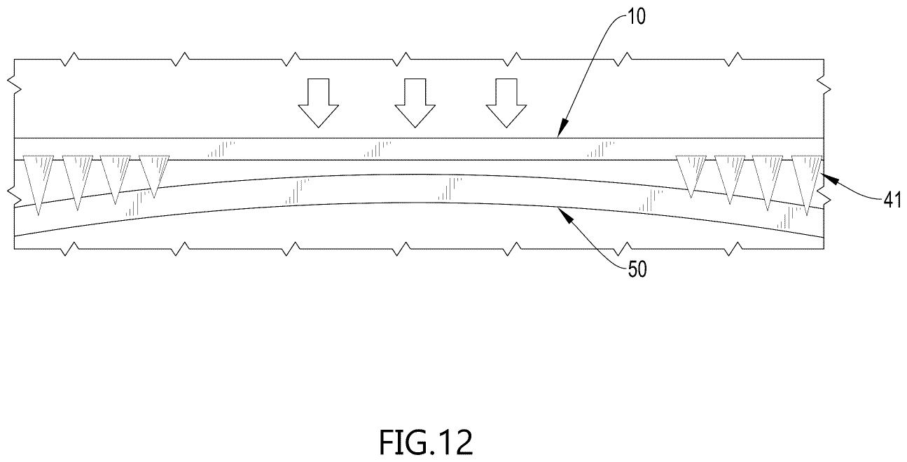

In the above embodiments, the single crystal/polycrystalline diamond or Vickers hardness exceeding 1000 kgf/mm² on the sheet body 30 is arranged in a linearly inclined pattern with a certain proportion. When the dresser 10 is pressed against the polishing pad 50, the center is raised, and a gradient height can be formed as shown in FIG. 12. After the dresser 10 is pressed, the piercing depth of the polishing pad 50 after the protrusion is still consistent, so that the dresser 10 is designed to have a cone height in which the outer cone height is higher than the central cone inside the dresser 10.

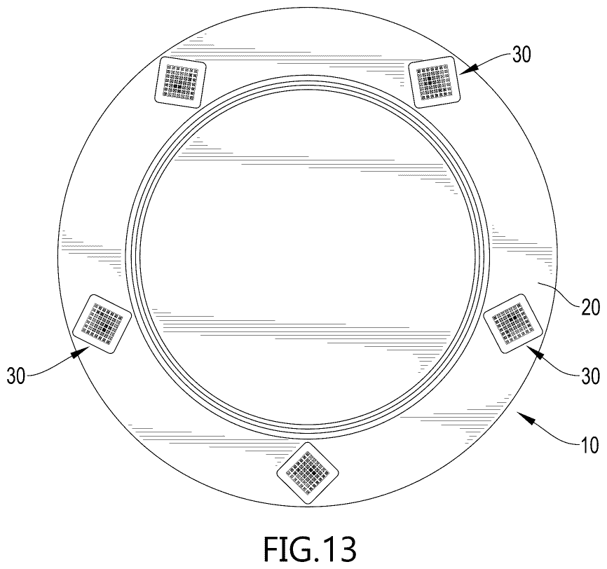

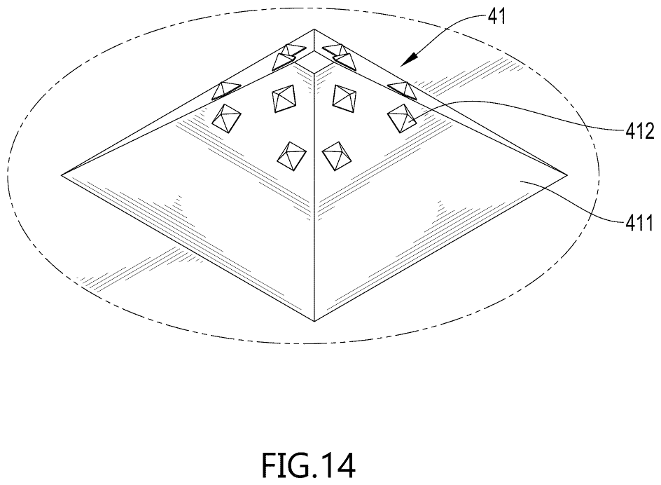

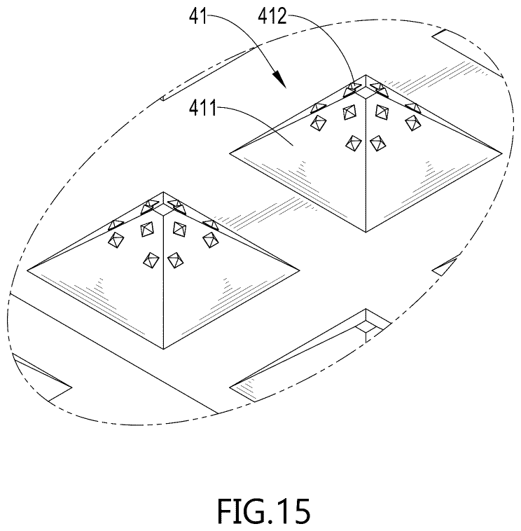

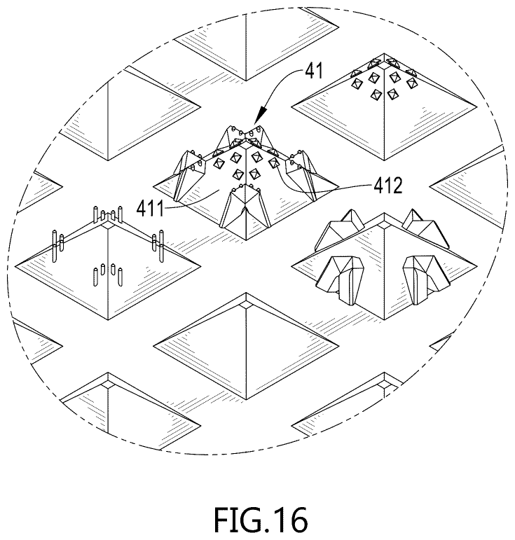

With the single crystal diamond/polycrystalline diamond or Vickers hardness exceeding 1000 kgf/mm² on the sheet body 30, as described above, the present invention can plan the laser path through a computer program, so that the diamond/polycrystalline diamond or Vickers hardness exceeding 1000 kgf/mm² high points of the sheet body in different functional areas can be carried out under the movement of a multi-axis direction mobile device, and the cone morphology and height creation of each surface on the sheet body 30 can be carried out. With reference to FIG. 13, single crystal/polycrystalline diamond or Vickers hardness exceeding 1000 kgf/mm² can be fixed on a substrate 20. Wherein, FIG. 14 is a partially enlarged cone shape of the sheet body 30, and FIGS. 15 and 16 are partially enlarged cone shapes of the sheet body 30.

In a specific embodiment, the single crystal diamond/polycrystalline diamond or Vickers hardness exceeding 1000 kgf/mm² on the sheet body 30 can be individually or combined into a dresser in a single system device, and then detected by an optical imaging device to provide height and cone x, y position information, and the height can be immediately dressed by laser light to complete the dresser 10 with the common height and coplanarity.

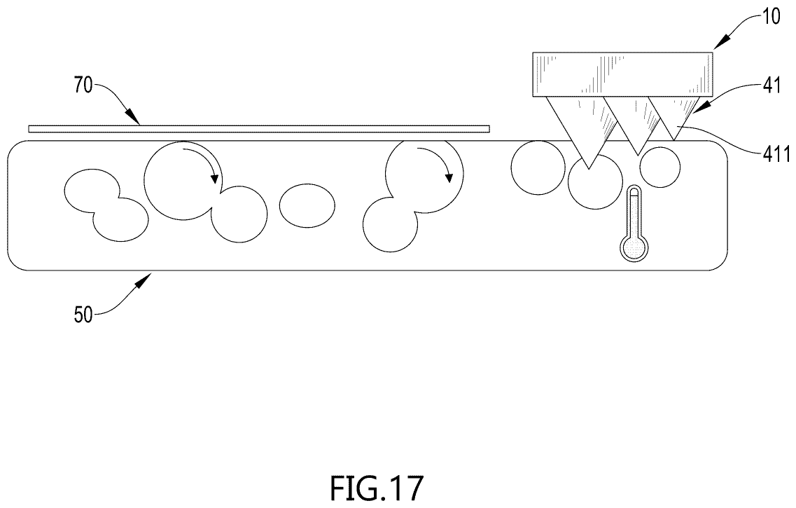

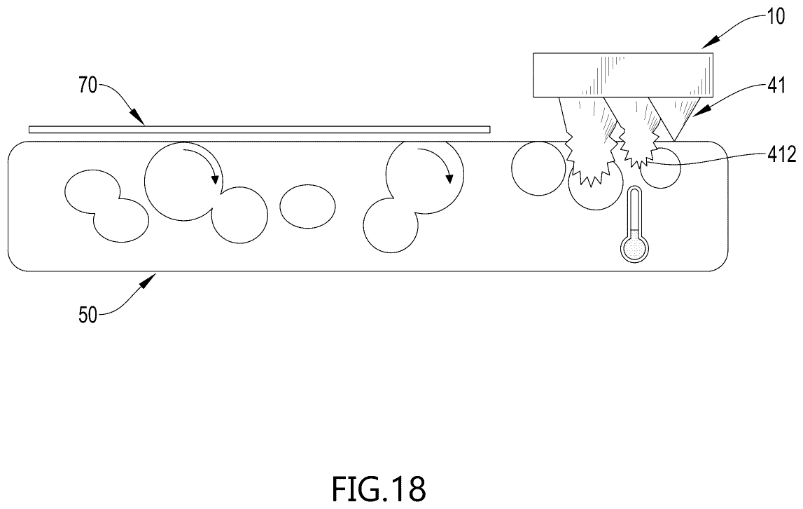

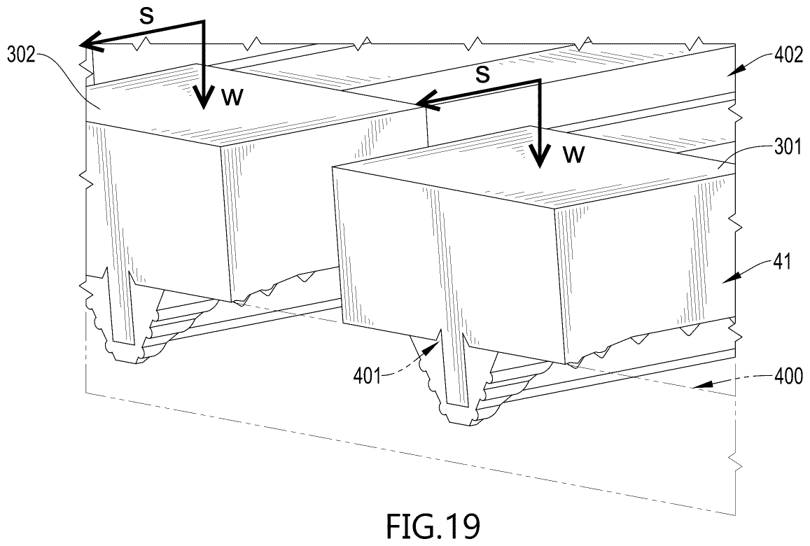

Therefore, the lateral morphology 3101/3111 of the new grooves generated by the present invention will allow the polishing pad 50 to contain more polishing liquid, and can continuously send the polishing liquid from the pores between the wafer and the polishing pad 50 during the grinding process. Therefore, the lateral morphology on the cone of the dresser 10 becomes the polishing liquid retained in the polishing pad 50. With reference to FIG. 17, the convex portion 411 (cone) can be grooved, scraped, and create fluff on the polishing pad 50. With reference to FIG. 18, the secondary convex portion 412 (secondary cone) creates pores on the side of the groove on the polishing pad 50; as shown in FIGS. 18 and 19, the side blade of the secondary cone creates side pores in the groove on the polishing pad 50.

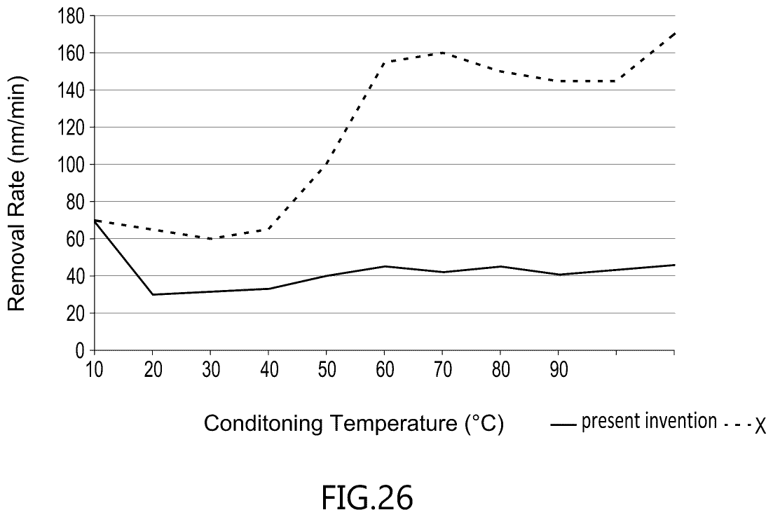

Through the above-mentioned technical features, after the dresser 10 of the present invention carves the polishing pad 50, it can contain more polishing fluid, form a cycle cooling and will suppress the thermal expansion of the polishing pad 50 to further ensure the polishing flattening result of the wafer. With reference to FIG. 26, as shown in the relationship diagram between temperature and material removal rate, it can be found that due to the three-or-more-dimensional operating mode of the present invention through linear and rotational interactions between the dresser 10 and the polishing pad 50, the dresser 10 can form more lateral grooves with a three-or-more-dimensional structural type on the polishing pad 50, and can contain more polishing fluid, so that the overall material removal rate (MRR) is more stable than the conventional dresser X.

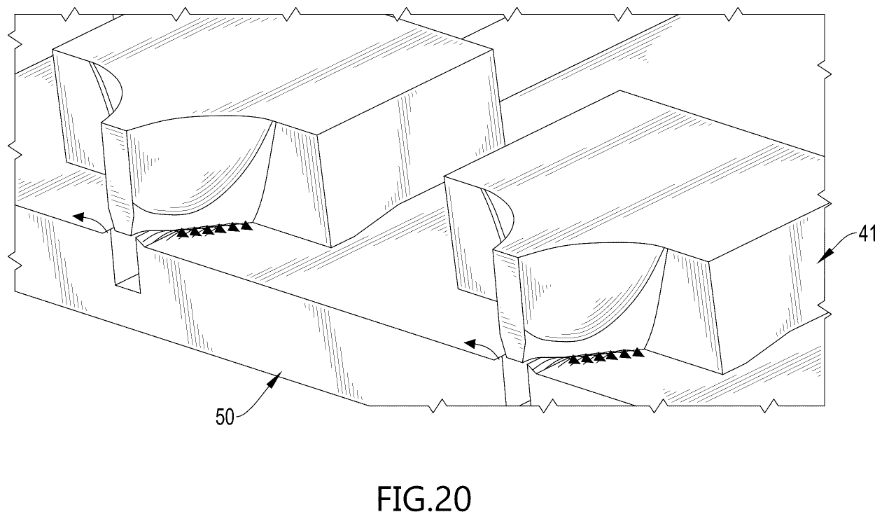

When the present invention is used, the high point 310 of the cone of the dresser 10 is inserted into the polishing pad 50. At this time, the deformation amount increases with the contact surface area in the downward pressure direction, but it is not easy to cause tearing. Therefore, it is necessary to tear through the small cone convex point 3101 first, and the polishing pad 50 can be smoothly torn in the downward pressure direction. As shown in FIG. 20, due to the relative movement between the polishing pad 50 and the dresser 10, the raised polishing pad convex material (arrow direction) will be arranged at the height of the cone peak 320, forming a method of pressing and removing the polishing pad convexity and subsequently creating more fluff.

Therefore, the sharp protrusion of the small high angle 3101/3111 on the diamond cone angle surface is conducive to the precise depth puncture of the polishing pad 50, downward and horizontally. The design of the cone angle of the dresser 10 can also be reduced; making the cone angle smaller, more cones can be added per unit area.

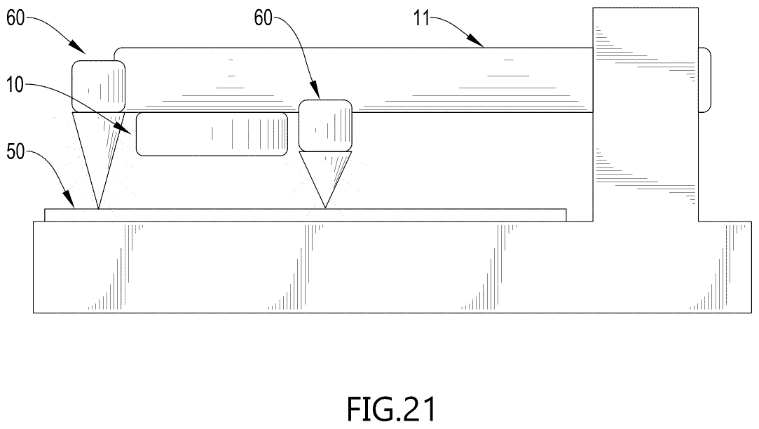

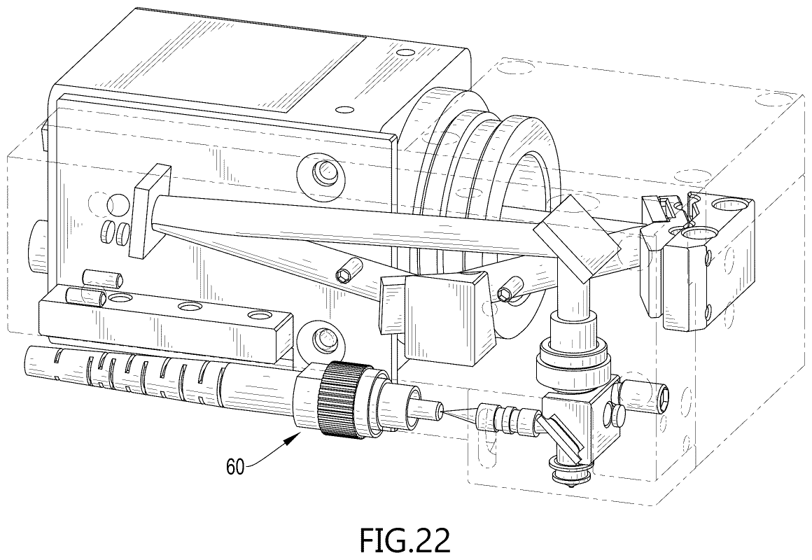

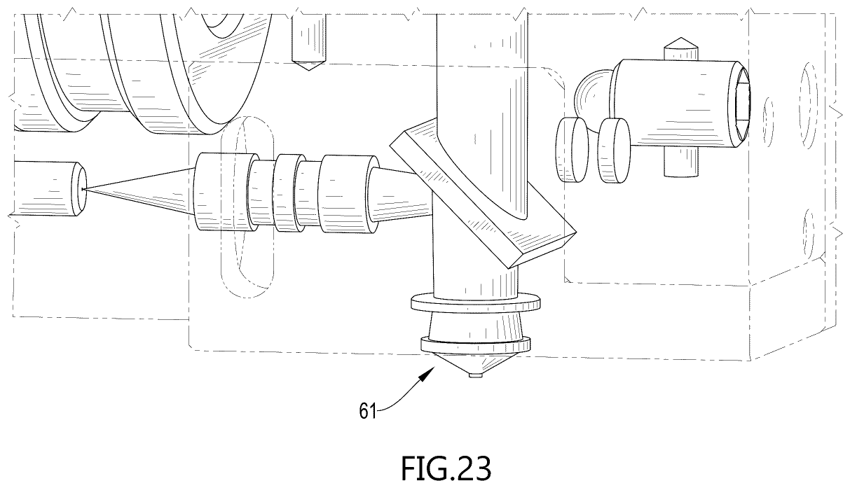

Importantly, the present invention can timely detect the surface texture and flatness of the polishing pad 50 and whether the high end of the cone of the dresser 10 is worn, which will directly make the CMP process transparent. With reference to FIGS. 21, 22, and 23, a lens module 60 (i.e. optical imaging device) for upward observation (observing the wear state of the dresser cone) and downward observation (3D texture of the polishing pad surface) is mounted on the CMP apparatus. The lens module 60 uses a meta-lens 61 to observe micro features and monitor the surface 3D texture by optical shear interference, and is equipped with an AI system (Weka/Deeplearnin4j/Saliency Map Viewer), which is used to observe the key areas of interest of the trained model in the input image. That is, the so-called “model vision”. The model will determine the category of the input image based on these areas of interest, and after identifying the polishing pad, polishing liquid, etc. with the object refractive index, reflected light intensity, and scattering data, the ultrafast laser is used to perform real-time regional morphology compensation of the dresser to achieve high flatness grinding of the wafer. With reference to FIGS. 22 and 23, an optical lens module 60 is formed by one or more meta-lenses 61, and the laser light is optically focused on the shear optical diffraction element. The CCD/CMOS sensor and the diffraction element detect the shear interference result at a fixed distance, and the shear interference result is used to reconstruct a 3D image. In this way, the surface geometry (flatness) of the polishing pad and the groove depth and uniformity can be observed to adjust the total height of dresser area of the CMP apparatus and the polishing pad movement parameters and statistical values. The optical lens module 60 is detected online in a narrow space, and its total thickness is <50 mm and can be embedded in any position of the apparatus.

The first embodiment is described below. Initially, the lens module 60 is used to identify the polishing pad 50, and a standardized environment such as reflectivity, light intensity, scattering, etc. is established (at this time, no polishing liquid is provided for the first round of dresser 10 polishing the polishing pad 50) and recorded and stored as reference 1. Enter the environment provided by the polishing liquid and use the lens module 60 to observe again (at this time, no wafer polishing is provided) and record and store it as reference 2. After identifying the unpolished and polished polishing pad 50 with references and 2 to establish basic data, the AI system begins training and learning to identify the surface of the polishing pad 50 and the characteristics of the polishing liquid. This is the first stage of learning.

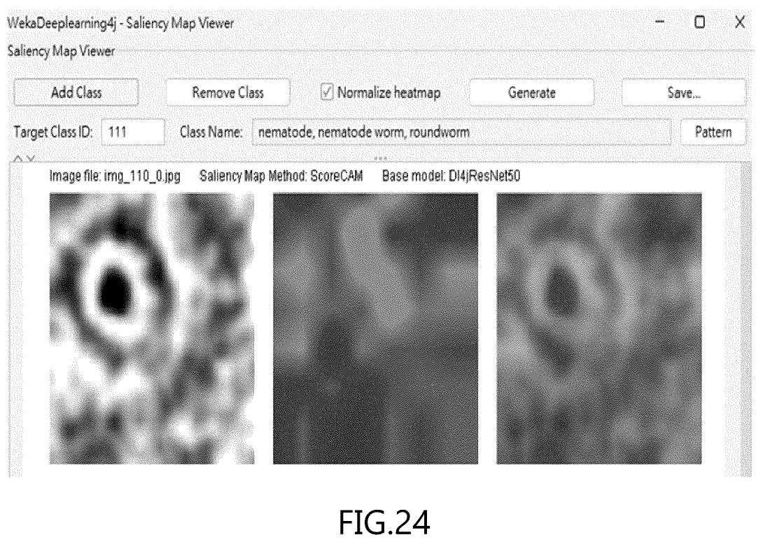

In the second stage, the wafer 70 is added for grinding, and the periodic reciprocating detection position is judged by the data of the first stage. For example, the image taking positions such as 3, 6, 9, and 12 o'clock are selected before the polishing pad 50 is dressed. The position is compared and learned, and the image is taken and measured. Through continuous learning of the AI system, the uneven area of the tiny features can be judged. As shown in FIG. 24, the FIG. on the left is the actual state (original input image) of a hole (uneven area) on the polishing pad. After learning, the AI system recognizes the feature as a point-shaped bright area (as shown in the middle figure, which shows the key area of the model, that is, the salient map). By overlapping the left image and the middle image, the superposition result as shown in the right image can be obtained and judgment can be made based on the image of this image, which is convenient for comparing the difference between the area noticed by the human eye and the model vision, and timely correcting the grinding parameters to grind the uneven area again. In addition, the captured multiple images are used for model training, verification and parameter adjustment by the software interface of the AI system (Deeplearning UI interface). For example, some images are used for training and learning of the AI system, and the remaining images are used for verification of the AI system. Preferably, 60˜70% of the images are used for training and learning, and 30˜40% of the images are used for verification.

The optical lens module 60 can preferably be mounted on the swing arm on the dresser 10. Or it can be preferably observed downward at an opening of the substrate 20 of the dresser 10. As shown in FIGS. 21, 22, and 23, the optical lens module 60 is formed by one or more meta-lenses 61, and is optically focused on the shear optical diffraction element through laser light. The CCD/CMOS sensor and the diffraction element detect the shear interference results at a fixed distance, and 3D image reconstruction is performed based on the shear interference results. In this way, the groove depth and surface roughness of the polishing pad can be observed, so as to adjust the movement parameters of the dresser 10 and the polishing pad 50 in the CMP apparatus. As shown in FIG. 21, it is a schematic diagram of the online detection of the optical lens module 60 in a narrow space. Its total thickness is less than 50 mm and can be embedded in any position of the apparatus. The optical lens module 60 may also be equipped with a self-cleaning system, such as air, liquid, ultrasound, etc., which can be judged by software to generate a self-cleaning action when the lens is dirty.

In the present invention, the cone is not limited to a continuous or discontinuous surface of a geometric shape. The cone is integrated with the sheet body 30, wherein the sheet body 30 can be removed by subtractive engineering such as laser or the cone morphology can be grown from the sheet body 30 by additive engineering. The cone tip, the knife cone or the corresponding point, line or surface of the cone are not limited. In addition, the substrate 20 refers to the metal body of the dresser 10, one end of which is connected and fixed to the device, and the other end is the sheet body 30 and the cone on the sheet body.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A dresser for a Chemical-Mechanical Polishing (CMP) process, the dresser comprising:
a substrate;
at least one sheet body disposed on a side face of the substrate; and
a modular grinding unit disposed on the at least one sheet body and having
multiple structures disposed on the at least one sheet body at spaced intervals, and each one of the multiple structures having
a convex portion, and the convex portions of the multiple structures having different heights.

2. The dresser for a CMP process as claimed in claim 1, wherein an optical imaging device is used to detect the height and position information of the convex portion of each structure, and perform height adjustment to complete a regional common height and coplanarity of the dresser, so that the regional common height ranges between 3 um and 10 um.

3. The dresser for a CMP process as claimed in claim 2, wherein each one of the multiple structures has at least one secondary convex portion formed around the convex portion, and a height of the at least one secondary convex portion is lower than the height of the convex portion.

4. The dresser for a CMP process as claimed in claim 3, wherein each one of the multiple structures is a cone made of single crystal diamond, polycrystalline diamond or a material with a Vickers hardness exceeding 1000 kgf/mm².

5. The dresser for a CMP process as claimed in claim 4, wherein the multiple structures are arranged on the at least one sheet body in a linearly spaced arrangement, a radially arranged arrangement or a matrix arrangement.

6. The dresser for a CMP process as claimed in claim 5, wherein the convex portion and each of the at least one secondary convex portion are formed on the structure by laser.

7. The dresser for a CMP process as claimed in claim 5, wherein the convex portion and each of the at least one secondary convex portion are formed on the structure by lamination.

8. The dresser for a CMP process as claimed in claim 1, wherein the modular grinding unit has convex portions arranged from two sides toward a middle with gradually decreasing heights.

9. The dresser for a CMP process as claimed in claim 1, wherein the modular grinding unit has convex portions with gradually decreasing heights arranged from a middle to two sides.

10. A CMP apparatus comprising:
a body having
a processing end; and
a processing platform;
a dresser as claimed in claim 2, disposed on the processing end of the body such that each one of the structures on the at least one sheet body faces the processing platform; and
a polishing pad disposed on the processing platform of the body and polished by the dresser.

11. A CMP apparatus comprising:
a body having
a processing end; and
a processing platform;
a dresser as claimed in claim 3, disposed on the processing end of the body such that each one of the structures on the at least one sheet body faces the processing platform; and
a polishing pad disposed on the processing platform of the body and polished by the dresser.

12. A CMP apparatus comprising:
a body having
a processing end; and
a processing platform;
a dresser as claimed in claim 4, disposed on the processing end of the body such that each one of the structures on the at least one sheet body faces the processing platform; and
a polishing pad disposed on the processing platform of the body and polished by the dresser.

13. A CMP apparatus comprising:
a body having
a processing end; and
a processing platform;
a dresser as claimed in claim 5, disposed on the processing end of the body such that each one of the structures on the at least one sheet body faces the processing platform; and
a polishing pad disposed on the processing platform of the body and polished by the dresser.

14. A CMP apparatus comprising:
a body having
a processing end; and
a processing platform;
a dresser as claimed in claim 6, disposed on the processing end of the body such that each one of the structures on the at least one sheet body faces the processing platform; and
a polishing pad disposed on the processing platform of the body and polished by the dresser.

15. A CMP apparatus comprising:
a body having
a processing end; and
a processing platform;
a dresser as claimed in claim 7, disposed on the processing end of the body such that each one of the structures on the at least one sheet body faces the processing platform; and
a polishing pad disposed on the processing platform of the body and polished by the dresser.

16. A CMP apparatus comprising:
a body having
a processing end; and
a processing platform;
a dresser as claimed in claim 8, disposed on the processing end of the body such that each one of the structures on the at least one sheet body faces the processing platform; and
a polishing pad disposed on the processing platform of the body and polished by the dresser.

17. A CMP apparatus comprising:
a body having
a processing end; and
a processing platform;
a dresser as claimed in claim 9, disposed on the processing end of the body such that each one of the structures on the at least one sheet body faces the processing platform; and
a polishing pad disposed on the processing platform of the body and polished by the dresser.

18. A CMP process comprising:
preparing a CMP apparatus as claimed in claim 10;
driving the dresser to move and rotate toward the polishing pad via the processing end of the body; and
polishing the polishing pad by the convex portions of each structure of the dresser to form regionalized polishing pad grooves with the common height and the coplanarity on the polishing pad, and to form lateral morphologies on the polishing pad through the at least one secondary convex portion of each structure.

19. A CMP process comprising:
preparing a CMP apparatus as claimed in claim 11;
driving the dresser to move and rotate toward the polishing pad via the processing end of the body; and
polishing the polishing pad by the convex portions of each structure of the dresser to form regionalized polishing pad grooves with the common height and the coplanarity on the polishing pad, and to form lateral morphologies on the polishing pad through the at least one secondary convex portion of each structure.

20. A CMP process comprising:
preparing a CMP apparatus as claimed in claim 12;
driving the dresser to move and rotate toward the polishing pad via the processing end of the body; and
polishing the polishing pad by the convex portions of each structure of the dresser to form regionalized polishing pad grooves with the common height and the coplanarity on the polishing pad, and to form lateral morphologies on the polishing pad through the at least one secondary convex portion of each structure.

21. A CMP process comprising:
preparing a CMP apparatus as claimed in claim 13;
driving the dresser to move and rotate toward the polishing pad via the processing end of the body; and
polishing the polishing pad by the convex portions of each structure of the dresser to form regionalized polishing pad grooves with the common height and the coplanarity on the polishing pad, and to form lateral morphologies on the polishing pad through the at least one secondary convex portion of each structure.

22. A CMP process comprising:
preparing a CMP apparatus as claimed in claim 14;
driving the dresser to move and rotate toward the polishing pad via the processing end of the body; and
polishing the polishing pad by the convex portions of each structure of the dresser to form regionalized polishing pad grooves with the common height and the coplanarity on the polishing pad, and to form lateral morphologies on the polishing pad through the at least one secondary convex portion of each structure.

23. A CMP process comprising:
preparing a CMP apparatus as claimed in claim 15;
driving the dresser to move and rotate toward the polishing pad via the processing end of the body; and
polishing the polishing pad by the convex portions of each structure of the dresser to form regionalized polishing pad grooves with the common height and the coplanarity on the polishing pad, and to form lateral morphologies on the polishing pad through the at least one secondary convex portion of each structure.

24. A CMP process comprising:
preparing a CMP apparatus as claimed in claim 16;
driving the dresser to move and rotate toward the polishing pad via the processing end of the body; and
polishing the polishing pad by the convex portions of each structure of the dresser to form regionalized polishing pad grooves with the common height and the coplanarity on the polishing pad, and to form lateral morphologies on the polishing pad through the at least one secondary convex portion of each structure.

25. A CMP process comprising:
preparing a CMP apparatus as claimed in claim 17;
driving the dresser to move and rotate toward the polishing pad via the processing end of the body; and
polishing the polishing pad by the convex portions of each structure of the dresser to form regionalized polishing pad grooves with the common height and the coplanarity on the polishing pad, and to form lateral morphologies on the polishing pad through the at least one secondary convex portion of each structure.

26. A method for monitoring pores of a polishing pad during a CMP process, the method comprising:
preparing a CMP apparatus as claimed in claim 10;
arranging a lens module on the CMP apparatus and using a meta-lens to observe micro features and perform 3D surface texturing and flatness monitoring by optical shearing interferometry;
using an AI system to identify the polishing pad, polishing fluids, and a wafer by refractive index, reflected light intensity, and scattering data; and
monitoring the pores of the polishing pad via the learning of the AI system to judge tiny features of the polishing pad.

27. A method for monitoring pores of a polishing pad during a CMP process, the method comprising:
preparing a CMP apparatus as claimed in claim 11;
arranging a lens module on the CMP apparatus and using a meta-lens to observe micro features and perform 3D surface texturing and flatness monitoring by optical shearing interferometry;
using an AI system to identify the polishing pad, polishing fluids, and a wafer by refractive index, reflected light intensity, and scattering data; and
monitoring the pores of the polishing pad via the learning of the AI system to judge tiny features of the polishing pad.

28. A method for monitoring pores of a polishing pad during a CMP process, the method comprising:
preparing a CMP apparatus as claimed in claim 12;
arranging a lens module on the CMP apparatus and using a meta-lens to observe micro features and perform 3D surface texturing and flatness monitoring by optical shearing interferometry;
using an AI system to identify the polishing pad, polishing fluids, and a wafer by refractive index, reflected light intensity, and scattering data; and
monitoring the pores of the polishing pad via the learning of the AI system to judge tiny features of the polishing pad.

29. A method for monitoring pores of a polishing pad during a CMP process, the method comprising:
preparing a CMP apparatus as claimed in claim 13;
arranging a lens module on the CMP apparatus and using a meta-lens to observe micro features and perform 3D surface texturing and flatness monitoring by optical shearing interferometry;
using an AI system to identify the polishing pad, polishing fluids, and a wafer by refractive index, reflected light intensity, and scattering data; and
monitoring the pores of the polishing pad via the learning of the AI system to judge tiny features of the polishing pad.

30. A method for monitoring pores of a polishing pad during a CMP process, the method comprising:
preparing a CMP apparatus as claimed in claim 14;
arranging a lens module on the CMP apparatus and using a meta-lens to observe micro features and perform 3D surface texturing and flatness monitoring by optical shearing interferometry;
using an AI system to identify the polishing pad, polishing fluids, and a wafer by refractive index, reflected light intensity, and scattering data; and
monitoring the pores of the polishing pad via the learning of the AI system to judge tiny features of the polishing pad.

31. A method for monitoring pores of a polishing pad during a CMP process, the method comprising:
preparing a CMP apparatus as claimed in claim 15;
arranging a lens module on the CMP apparatus and using a meta-lens to observe micro features and perform 3D surface texturing and flatness monitoring by optical shearing interferometry;
using an AI system to identify the polishing pad, polishing fluids, and a wafer by refractive index, reflected light intensity, and scattering data; and
monitoring the pores of the polishing pad via the learning of the AI system to judge tiny features of the polishing pad.

32. A method for monitoring pores of a polishing pad during a CMP process, the method comprising:
preparing a CMP apparatus as claimed in claim 16;
arranging a lens module on the CMP apparatus and using a meta-lens to observe micro features and perform 3D surface texturing and flatness monitoring by optical shearing interferometry;
using an AI system to identify the polishing pad, polishing fluids, and a wafer by refractive index, reflected light intensity, and scattering data; and
monitoring the pores of the polishing pad via the learning of the AI system to judge tiny features of the polishing pad.

33. A method for monitoring pores of a polishing pad during a CMP process, the method comprising:
preparing a CMP apparatus as claimed in claim 17;
arranging a lens module on the CMP apparatus and using a meta-lens to observe micro features and perform 3D surface texturing and flatness monitoring by optical shearing interferometry;
using an AI system to identify the polishing pad, polishing fluids, and a wafer by refractive index, reflected light intensity, and scattering data; and
monitoring the pores of the polishing pad via the learning of the AI system to judge tiny features of the polishing pad.
